(19) United States
(12) Patent Application Publication
(10) Pub. No.: US 2013/0058046 A1
(43) Pub. Date: Mar. 7, 2013

(54) PRINTED CIRCUIT BOARD ASSEMBLY AND MANUFACTURING METHOD THEREOF

(71) Applicants: Sung Ki KIM, Seoul (KR); Sang Hak KIM, Yongin-si (KR)

(72) Inventors: Sung Ki KIM, Seoul (KR); Sang Hak KIM, Yongin-si (KR)

(73) Assignee: SAMSUNG ELECTRONICS CO., LTD., Suwon-si (KR)

(21) Appl. No.: 13/603,712

(22) Filed: Sep. 5, 2012

(30) Foreign Application Priority Data
Sep. 5, 2011 (KR) 10-2011-0089418

(51) Int. Cl. H05K 7/20; F28F 7/00; B05D 5/00; H05K 3/30

(52) U.S. Cl. 361/720; 29/832; 165/185; 427/58

(57) ABSTRACT

A printed circuit board assembly and a manufacturing method thereof are provided. The method includes mounting an electrical component on a printed circuit board; depositing a curable gel on the electrical component by discharging the curable gel through a nozzle; and hardening the curable gel deposited on the electrical component to form a heat radiation member.

### CROSS-REFERENCE TO RELATED APPLICATION

This application claims priority from Korean Patent Application No. 2011-0089418, filed on Sep. 5, 2011 in the Korean Intellectual Property Office, the disclosure of which is incorporated herein by reference in its entirety.

### BACKGROUND

1. Field

Methods and apparatuses consistent with exemplary embodiments relate to a printed circuit board assembly formed by mounting an electrical component on a printed circuit board, and a manufacturing method thereof.

2. Description of the Related Art

In general, a printed circuit board assembly is formed by mounting various electrical components on a printed circuit board. Recently, a surface mounting apparatus capable of manufacturing a printed circuit board assembly by mounting electrical components on a printed circuit board using an automatic mounting method with a robot following a trend of factory automation is being widely used.

The printed circuit board assembly as described above includes a printed circuit board and various electrical components that are mounted on the printed circuit board. In a case of a central processing unit (CPU) and an integrated circuit (IC) as electrical components mounted on the printed circuit board, a large amount of heat is generated when the CPU and IC are operated. Thus, a heat radiation member is may be disposed on electrical components so that the electrical components may be cooled off in a short period of time.

In general, a heat radiation member is made of a metallic material having high heat conductivity, and is attached on an electrical component by use of a double-sided tape.

However, an automatic mounting method for attaching a heat radiation member to an electrical component with a double-sided tape using is considered to be a difficult method. As a result, a heat radiation member is manually attached on an electrical component in many cases.

In addition, with a method of attaching a heat radiation member to an electrical component by use of a double-sided tape, a heat radiation member may be difficult to be disposed on an electrical component having a curved surface or an irregular shape.

### SUMMARY

One or more exemplary embodiments provide a printed circuit board assembly having a heat radiation member mounted on an electrical component using an automatic mounting method, and a manufacturing method thereof.

One or more embodiments also provide a manufacturing method of a printed circuit board assembly capable of having a heat radiation member disposed on a surface of an electrical component regardless of a condition of the electrical component, and a printed circuit board assembly manufactured using the same.

In accordance with an aspect of an exemplary embodiment, there is provided a printed circuit board assembly including a printed circuit board, an electrical component mounted on the printed circuit board; and a heat radiation member comprising a hardened curable gel deposited on the electrical component.

The heat radiation member may be formed to have at least one protrusion.

The heat radiation member may have a heat conductivity of 1.5 W/mK or more.

The heat radiation member may is formed to have at least one protrusion having a width that becomes narrower while extending outward from a surface of the radiation member contacting the electrical component.

The heat radiation member may be formed to have at least one protrusion having a diameter that becomes narrower while extending outward from a surface of the radiation member contacting the electrical component.

A contact area between the electrical component and the heat radiation member may be increased in proportion to time taken for depositing the curable gel thereto.

In accordance with an aspect of another exemplary embodiment, there is provided a method of manufacturing a printed circuit board assembly, the method including mounting an electrical component on a printed circuit board; depositing a curable gel on the electrical component by discharging the curable gel through a nozzle; and hardening the curable gel deposited on the electrical component to form a heat radiation member.

The depositing the curable gel on the electrical component may include depositing the curable gel on the electrical component to form at least one protrusion in the curable gel.

The depositing the curable gel on the electrical component may include depositing the curable gel on the electrical component by discharging the curable gel through the nozzle for a predetermined time interval so as to form a plurality of protrusions in the curable gel.

In the depositing of the curable gel on the electrical component, the at least one protrusion may be formed in a moving direction of the printed circuit board.

In the depositing of the curable gel on the electrical component, a plurality of protrusions may be formed in parallel to each other in a direction perpendicular to a moving direction of the printed circuit board.

In the depositing of the curable gel on the electrical component, a contact area between the electrical component and the heat radiation member may be increased in proportion to the time taken for discharging the curable gel through the nozzle.

### BRIEF DESCRIPTION OF THE DRAWINGS

The above and other aspects will become apparent and more readily appreciated from the following description of the exemplary embodiments, taken in conjunction with the accompanying drawings of which:

FIG. 1 is a perspective view showing a surface mounting apparatus and a printed circuit board assembly according to an exemplary embodiment.

FIG. 2 is a perspective view showing a state of a curable gel being deposited on a printed circuit board assembly by a surface mounting apparatus according to an exemplary embodiment.

FIG. 3 is a cross-sectional view showing a change of a shape of a curable gel according to a time taken for the curable gel being deposited by a surface mounting apparatus according to an exemplary embodiment.

FIG. 4 is a cross-sectional view showing a change of a shape of a curable gel according to a movement of a nozzle of a surface mounting apparatus according to an exemplary embodiment.

FIG. 5 is a flow chart showing a manufacturing method of a printed circuit board assembly according to an exemplary embodiment.

FIG. 6 is a perspective view showing a state of a curable gel being deposited on a printed circuit board by a surface mounting apparatus according to an exemplary embodiment.

### DETAILED DESCRIPTION OF EXEMPLARY EMBODIMENTS

Reference will now be made to the exemplary embodiments, with reference to the accompanying drawings, wherein like reference numerals refer to like elements throughout.

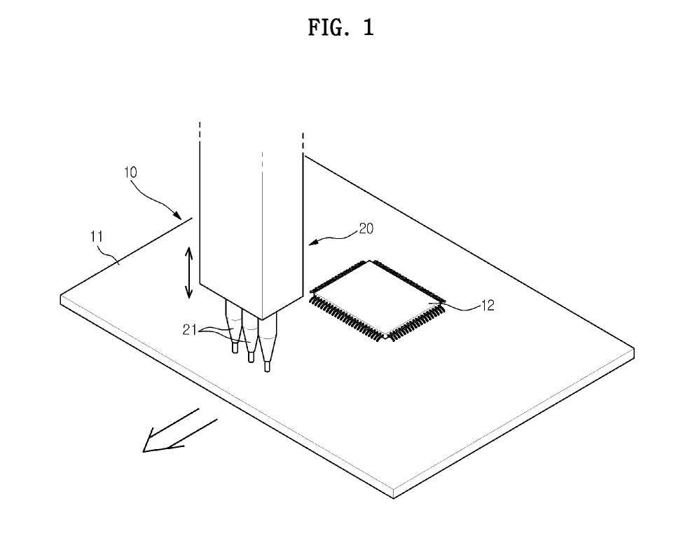

As illustrated on FIG. 1, a printed circuit board assembly 10 manufactured by a surface mounting apparatus 20 according to an exemplary embodiment includes a printed circuit board 11 and an electrical component 12 mounted on the printed circuit board 11.

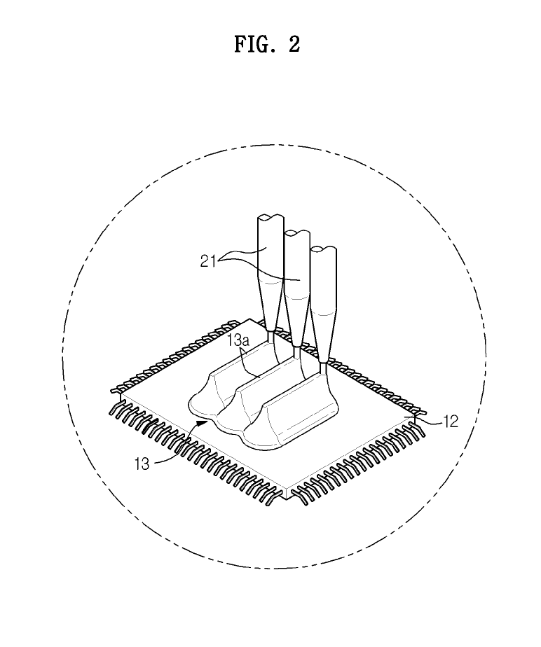

The surface mounting apparatus 20 includes at least one nozzle 21 that deposits or sprays a curable gel on the electrical component 12 to form a heat radiation member 13 (see FIG. 2) on the electrical component 12 mounted to the printed circuit board 11.

The electrical component 12 may be a central processing unit (CPU) or an integrated circuit (IC). The electrical component 12 generates a heat when operated, and may be cooled by the heat radiation member 13.

The heat radiation member 13 is formed on the electrical component 12, and thus the heat generated at the electrical component 12 may be heat-exchanged with air, and thereby the electrical component 12 is cooled. As illustrated in FIG. 2, a curable gel is discharged through the nozzle 21 of the surface mounting apparatus 20 and deposited in a predetermined shape on the electrical component 12. The curable gel on the electrical component 12 is hardened, and thereby the heat radiation member 13 is formed. The heat radiation member 13 according to the exemplary embodiment is provided with a plurality of protrusions 13a formed thereto, and the plurality of protrusions 13a protrude toward an upper side thereof so that heat radiation is facilitated.

As described above, as the curable gel is deposited on the electrical component 12 through the nozzle 21, and the heat radiation member 13 is formed by hardening the curable gel. The hardened heat radiation member 13 is firmly attached to the electrical component 12, even in a state when no adhesive medium, such as an adhesive or a double-sided tape, is present. Thus, the heat radiation member 13 may be mounted on the electrical component 12 by use of the automatic mounting method through the surface mounting apparatus 20.

The curable gel may be formed with various materials such as resin, silicon, or a mixture of thereof, and is provided with a certain viscosity. The curable gel may be hardened by ultraviolet (UV) light, a heating process, or the lapse of time. After the curable gel is hardened as the heat radiation member 13, the heat radiation member 13 may have a heat conductivity of 1.5 W/mK or above.

The curable gel, by the characteristic of the material in a gel state, is provided with the shape thereof that may be freely changed. That is, in a process of the curable gel being deposited on the electrical component 12, the surface of the curable gel, which is in contact with the electrical component 12 after the curable gel is deposited on the electrical component 12, is changed into a shape that corresponds to the surface of the electrical component 12. Accordingly, even in a case when the electrical component 12 is provided with a curved surface or an irregular shape thereof, the curable gel is cured in a state of being completely attached on the surface of the electrical component 12. In this state, the curable gel is hardened to form the heat radiation member 13 on the electrical component 12, regardless of the condition of a surface of the electrical component 12.

In addition, as the heat radiation member 13 is completely attached to a surface of the electrical component 12, a sufficient heat transfer performance may be attained even in a case when the heat radiation member 13 is formed with a material having a relatively lower heat conductivity in comparison to a metal.

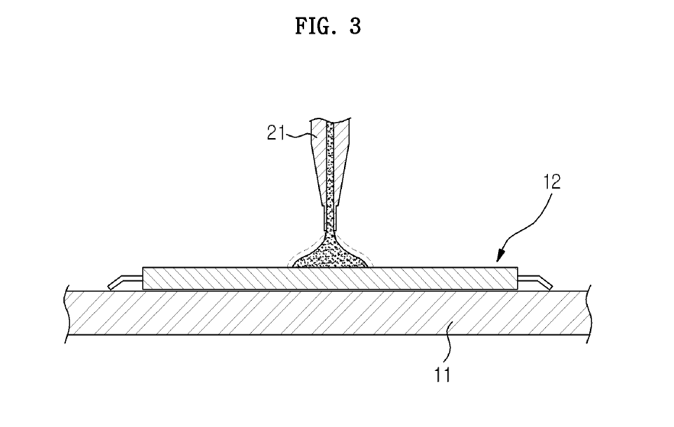

As illustrated on FIG. 3, the contact area formed by the curable gel in between the heat radiation member 13 and the electrical component 12 may be gradually increased in proportion to the time taken to deposit the curable gel through the nozzle 21.

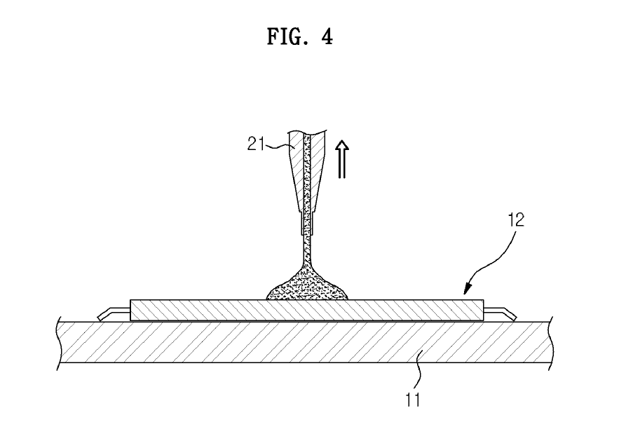

In addition, as illustrated on FIG. 4, the nozzle 21 is installed in a way that the nozzle 21 may be positioned above the electrical component 12 and the printed circuit board 11, and raised or lowered towards the electrical component 12 and printed circuit board 11. Thus, as the nozzle 21 is moved toward an upper side of the electrical component 12, the curable gel is discharged through the nozzle 21, and thereby a height of the protrusion 13a formed at the heat radiation member 13 may be controlled.

The nozzle 21 according to the exemplary embodiment is configured to deposit the curable gel in lengthways with respect to a moving direction of the printed circuit board 11 that moves toward one direction, and is made in a way that the curable gel is deposited while having a width thereof becoming narrower while proceeding from a lower side to an upper side.

In addition, the surface mounting apparatus 20 according to the exemplary embodiment may include a plurality of nozzles 21 aligned in parallel to each other while extending in a direction perpendicular to a moving direction of the printed circuit board 11, thereby forming the heat radiation member 13 having the plurality of protrusions 13a aligned in parallel at certain intervals while being formed in a direction perpendicular to a moving direction of the printed circuit board 11.

Hereinafter, a manufacturing method of the printed circuit board assembly for forming the heat radiation member 13 on the electrical component 12 of the printed circuit board assembly 10 through the surface mounting apparatus 20, will be described.

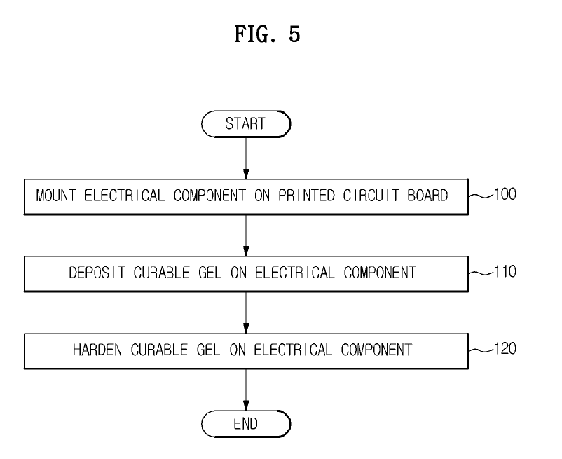

As illustrated on FIG. 5, the manufacturing method of the printed circuit board assembly includes mounting the electrical component 12 on the printed circuit board 11, for example, by moving in one direction by use of a robot (100), depositing a curable gel having a certain shape on the electrical component 12 mounted on the printed circuit board 11 through the nozzle 21 (110), and hardening the curable gel on the electrical component 12 (120), thereby forming the heat radiation member 13 on the electrical component 12.

In the depositing of the curable gel on the printed circuit board 11 through the nozzle 21 at operation 110, as a large amount of the curable gel is widely dispersed through the nozzle 21 in proportion to the time for the curable gel being deposited, the contact area in between the heat radiation member 13 formed as the curable gel is hardened and the electrical component 12 is increased in proportion to the time taken for the curable gel being deposited, and the heat radiation area of the heat radiation member 13 is also increased in proportion.

In the depositing of the curable gel on the printed circuit board 11 through the nozzle 21 at operation 110, the nozzle 21 as described above is made to deposit the curable gel in lengthways with respect to a moving direction of the printed circuit board 11, and is made in a way that the curable gel is deposited while having a width thereof becoming narrower while proceeding from a lower side to an upper side.

In addition, as described above, as the plurality of nozzles 21 are aligned in parallel to each other while being formed in a direction perpendicular to a moving direction of the printed circuit board 11, each curable gel deposited in a certain shape through each of the plurality of nozzles 21 at operation 110 is spaced apart from one another in a parallel manner while being formed in a direction perpendicular to a moving direction of the printed circuit board 11. In the state as such, as the curable gels are hardened, the heat radiation member 13 has the plurality of protrusions 13a formed on the electrical component 12, the plurality of protrusions 13a extending in the moving direction of the printed circuit board 11 in parallel to each other at certain intervals while being formed in the direction perpendicular to the moving direction of the printed circuit board 11. The protrusion 13a of the heat radiation member 13 according to the exemplary embodiment is formed with a width that is gradually narrowed while extending from a lower side thereof to an upper side thereof.

The nozzle 21 is configured to deposit the curable gel in one lengthways direction to form the heat radiation member 13 having the protrusion 13a extending lengthwise along the moving direction of the printed circuit board 11 on the electrical component 12, but is not limited hereto, and other protrusions having different shapes may be applied.

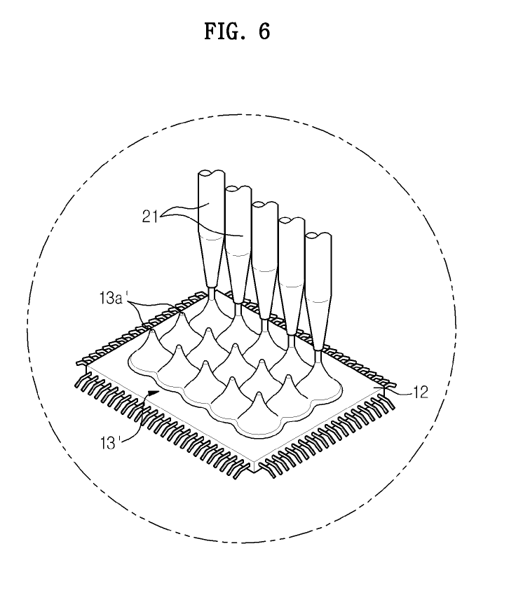

FIG. 6 illustrates an exemplary embodiment in which the nozzle 21 discharges the curable gel, while proceeding from a lower side thereof to an upper side thereof. The deposited curable gel has a diameter that is narrowed, so that a protrusion 13a′, which is provided with a diameter that becomes narrower while extending from a lower side thereof to an upper side thereof, is formed. As a result, a heat radiation member 13′ is formed to have the protrusion 13a′ in a shape of a cone.

The surface mounting apparatus 20 according to an exemplary embodiment includes the plurality of nozzles 21 aligned in parallel to each other while extending in the direction perpendicular to a moving direction of the printed circuit board 11. By depositing the curable gel on the printed circuit board 11 through the nozzles 21, the heat radiation member 13 is formed to have the plurality of protrusions 13a′ aligned in parallel to each other while being formed in the direction perpendicular to the moving direction of the printed circuit board 11. In this case, the curable gel is deposited at certain time intervals so that the plurality of protrusions 13a are sequentially formed in the moving direction of the printed circuit board 11. That is, the heat radiation member 13 has the plurality of protrusions 13a′ sequentially formed on the electrical component 12 in the moving direction of the printed circuit board 11 while being formed in the direction perpendicular to the moving direction of the printed circuit board 11 in parallel to each other.

The shapes of the heat radiation members 13 and 13′ are not limited to those described above, and various shapes of heat radiation members may be mounted on the electrical component 12 through the surface mounting apparatus 20, for example, to increase a contact area with air.

The heat radiation members 13 and 13′ of the exemplary embodiments are provided with the plurality of protrusions 13a and 13a′, but are not limited hereto, and a single protrusion may be formed at the heat radiation member according to a design.

Although a few exemplary embodiments have been shown and described, it would be appreciated by those skilled in the art that changes may be made in the exemplary embodiments without departing from the principles and spirit of the disclosure, the scope of which is defined in the claims and their equivalents.

What is claimed is:

1. A printed circuit board assembly comprising:
a printed circuit board;
an electrical component mounted on the printed circuit board; and
a heat radiation member comprising a hardened curable gel deposited on the electrical component.

2. The printed circuit board assembly of claim 1, wherein the heat radiation member is formed to have at least one protrusion.

3. The printed circuit board assembly of claim 1, wherein the heat radiation member has a heat conductivity of 1.5 W/mK or more.

4. The printed circuit board assembly of claim 1, wherein the heat radiation member is formed to have at least one protrusion having a width that becomes narrower while extending outward from a surface of the radiation member contacting the electrical component.

5. The printed circuit board assembly of claim 1, wherein the heat radiation member is formed to have at least one protrusion having a diameter that becomes narrower while extending outward from a surface of the radiation member contacting the electrical component.

6. The printed circuit board assembly of claim 1, wherein a contact area between the electrical component and the heat radiation member is increased in proportion to time taken for deposition of the curable gel onto the electrical component.

7. A method of manufacturing a printed circuit board assembly, the method comprising:
mounting an electrical component on a printed circuit board;
depositing a curable gel on the electrical component by discharging the curable gel through a nozzle; and
hardening the curable gel deposited on the electrical component to form a heat radiation member.

8. The method of claim 7, wherein the depositing the curable gel on the electrical component comprises depositing the curable gel on the electrical component to form at least one protrusion in the curable gel.

9. The method of claim 8, wherein the depositing the curable gel on the electrical component comprises depositing the curable gel on the electrical component by discharging the curable gel through the nozzle for a predetermined time interval so as to form a plurality of protrusions in the curable gel.

10. The method of claim 8, wherein in the depositing the curable gel on the electrical component, the at least one protrusion is formed in a moving direction of the printed circuit board.

11. The method of claim 8, wherein in the depositing the curable gel on the electrical component, a plurality of protrusions are formed in parallel to each other in a direction perpendicular to a moving direction of the printed circuit board.

12. The method of claim 7, wherein in the depositing the curable gel on the electrical component, a contact area between the electrical component and the heat radiation member is increased in proportion to time taken for discharging the curable gel through the nozzle.

13. A heat radiation member comprising:
a curable gel deposited on an electrical component, the curable gel having at least one fin extending outward from a surface of the curable gel contacting the electrical component.

14. The heat radiation member of claim 13, wherein the curable gel is hardened on the electrical component to form the heat radiation member.

15. The heat radiation member of claim 14, wherein the curable gel is applied to the electrical component in a shape of the heat radiation member.

16. The heat radiation member of claim 15, wherein the curable gel applied to the electrical component in the shape of the heat radiation member is cured on the electrical component in the shape of the heat radiation member.

17. A method of manufacturing a heat radiation member of an electrical component, the method comprising:
applying a curable gel to a surface of the electrical component; and
curing the curable gel as the heat radiation member.

18. The method of claim 17, wherein the applying comprises applying the curable gel to the electrical component in a shape of the heat radiation member.

19. The method of claim 18, wherein the curing comprises curing the curable gel applied to the electrical component in the shape of the heat radiation member.

20. The method of claim 17, wherein the applying comprises discharging the curable gel through a nozzle to deposit the curable gel on a surface of the electrical component in a shape of the heat radiation member, and
wherein the curing comprises curing the curable gel in the shape of the heat radiation member on the surface of the electrical component.
